(19) United States
(12) Patent Application Publication
(10) Pub. No.: US 2026/0304824 A1
(43) Pub. Date: Oct. 1, 2026

(54) METHOD FOR MANUFACTURING MOSFET DEVICE AND MOSFET DEVICE THEREOF

(71) Applicant: CHONGQING SIMIC SEMICONDUCTOR LIMITED, CHONGQING (CN)

(72) Inventor: LI YANG, CHONGQING (CN)

(21) Appl. No.: 19/572,901

(22) Filed: Mar. 20, 2026

(30) Foreign Application Priority Data
Mar. 28, 2025 (CN) 202510407996.6

(51) Int. Cl. H10D 30/63; H10D 30/01; H10D 62/10; H10D 62/60; H10D 64/27; H10W 10/00; H10W 72/00

(52) U.S. Cl. CPC H10D 30/63; H10D 30/025; H10D 62/102; H10D 62/60; H10D 64/513; H10W 10/011; H10W 72/01953

(57) ABSTRACT

A method for manufacturing a metal-oxide-semiconductor field-effect transistor (MOSFET) device and a MOSFET device thereof are provided. The method includes forming gate interconnection structures, trench gates, and voltage-withstand rings on a substrate with high resistivity; performing first ion implantation and first high-temperature activation to form a body region, performing second ion implantation and second high-temperature activation to form a source region; depositing an isolation layer, and forming gate interconnection metal contacts, source region metal contacts, and a cut-off ring metal contact on the isolation layer, forming a gate metal, a source metal, and a cut-off ring metal; thinning the substrate from a back surface thereof; and forming a drain metal on the back surface of the substrate.

### TECHNICAL FIELD

The present disclosure relates to a field of power semiconductor devices. and in particular to a method for manufacturing a metal-oxide-semiconductor field-effect transistor (MOSFET) device with a single-crystal substrate as an epitaxial region and a MOSFET device thereof.

### BACKGROUND

Chip-scale packaged bi-directional metal-oxide-semiconductor field-effect transistor (MOSFET) devices are mainly used in charge and discharge protection circuits. A conduction current in a substrate and a backside metal of a MOSFET device is horizontal. A resistance of the MOSFET device consists of an epitaxial layer resistance, a substrate resistance, and a backside metal resistance. Since the epitaxial layer resistance and the substrate resistance are significantly greater than the metal resistance, a thicker epitaxial layer needs to be grown during MOSFET fabrication, which increases process steps and manufacturing costs.

### SUMMARY

In view of defects in the prior art, the present disclosure provides a method for manufacturing a metal-oxide-semiconductor field-effect transistor (MOSFET) device with a single-crystal substrate as an epitaxial region.

The method comprises steps S110-S170.

The step S110 comprises providing a substrate having a high resistivity.

The step S120 comprises forming trenches on the substrate by photolithography and etching. The trenches comprise gate interconnection trenches, active region gate trenches, and voltage-withstand ring trenches.

The step S130 comprises forming gate interconnection structures respectively in the gate interconnection trenches, forming trench gates respectively in the active region gate trenches, and forming voltage-withstand rings respectively in the voltage-withstand ring trenches.

The step S140 comprises performing first ion implantation and first high-temperature activation to form a body region, and performing second ion implantation and second high-temperature activation to form a source region.

The step S150 comprises depositing an isolation layer, and forming gate interconnection metal contacts, source region metal contacts, and a cut-off ring metal contact on the isolation layer. The gate interconnection metal contacts, the source region metal contacts, and the cut-off ring metal contact run through the isolation layer. The gate interconnection metal contacts are respectively connected to the gate interconnection structures, the source region metal contacts are connected to the source region, and the cut-off ring metal contact is connected to one of the voltage-withstand rings farthest away from the gate interconnection structures.

The step S160 comprises performing metallization deposition on the isolation layer, and forming bonding pads by photolithography and etching, wherein the bonding pads comprise a gate metal connected to the gate interconnection metal contacts, a source metal connected to the source region contacts, and a cut-off ring metal connected to the cut-off ring contacts. The gate metal, the source metal and the cut-off ring metal are isolated from each other.

The step S180 comprises thinning the substrate from a back surface thereof, and forming a drain metal on the back surface of the substrate.

The present disclosure further provides a MOSFET device with a single-crystal substrate as an epitaxial region. The MOSFET device is manufactured by the method described above.

In a manufacturing process of the MOSFET device of the present disclosure, a thermal process at high temperatures adjusts a resistivity of the substrate. As a result, compared to a conventional MOSFET device that has a substrate with low resistivity, the substrate with high resistivity that meets requirements of a voltage-withstand layer of the MOSFET devices is obtained. By controlling a temperature during the high-temperature process, an originally graded doping concentration in the substrate is redistributed through diffusion, thereby achieving the substrate with a doping concentration roughly equal to that of the voltage-withstand layer. In this way, the MOSFET device is enabled to meet a desired voltage-withstand specification. In the MOSFET device of the present disclosure, since no epitaxial layer needs to be grown, the manufacturing process is simplified, and the manufacturing cost is reduced.

### BRIEF DESCRIPTION OF DRAWINGS

FIG. 1 is a schematic diagram of a conventional MOSFET device in the prior art.

FIG. 2 is a flow chart of a method for manufacturing a MOSFET device according to one embodiment of the present disclosure.

FIG. 3 is a schematic diagram of a substrate after trenches are formed.

FIG. 4 is a schematic diagram of a structure obtained after growing gate oxide layers in the trenches.

FIG. 5 is a schematic diagram of a structure obtained after forming gate interconnection structure, trench gates, and voltage-withstand rings.

FIG. 6 is a schematic diagram of a structure obtained after forming a body region and a source region.

FIG. 7 is a schematic diagram of a structure obtained after depositing an isolation layer and forming gate interconnect metal contacts, source region metal contacts, and cutoff ring metal contacts.

FIG. 8 is a schematic diagram of a structure obtained after forming a gate metal, a source metal, and a cutoff ring metal.

FIG. 9 is a schematic diagram of the MOSFET device obtained after forming protective layers and a drain metal.

FIG. 10 is a flow chart of the method for manufacturing the MOSFET device according to another embodiment of the present disclosure.

FIG. 11 is a schematic diagram of a structure obtained after a thin epitaxial layer is grown.

FIG. 12 is a schematic diagram of the MOSFET device according to another embodiment of the present disclosure.

### DETAILED DESCRIPTION

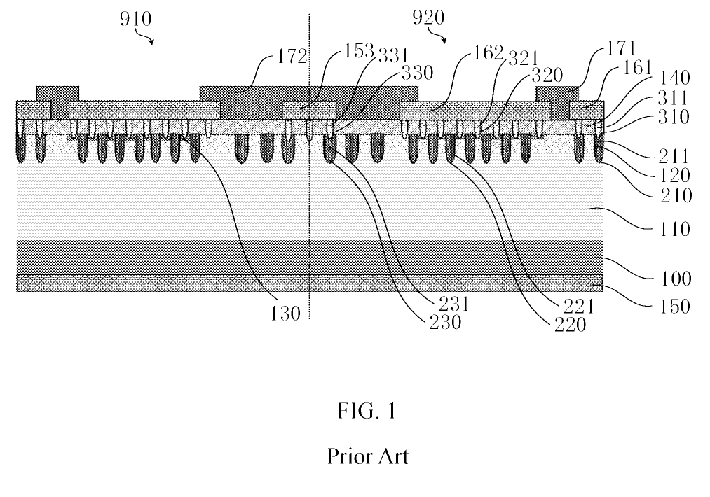

As shown in FIG. 1, a thicker epitaxial layer 110 needs to be grown during a manufacturing process of a metal-oxide-semiconductor field-effect transistor (MOSFET) device, which increases process steps and manufacturing costs.

### Embodiment 1

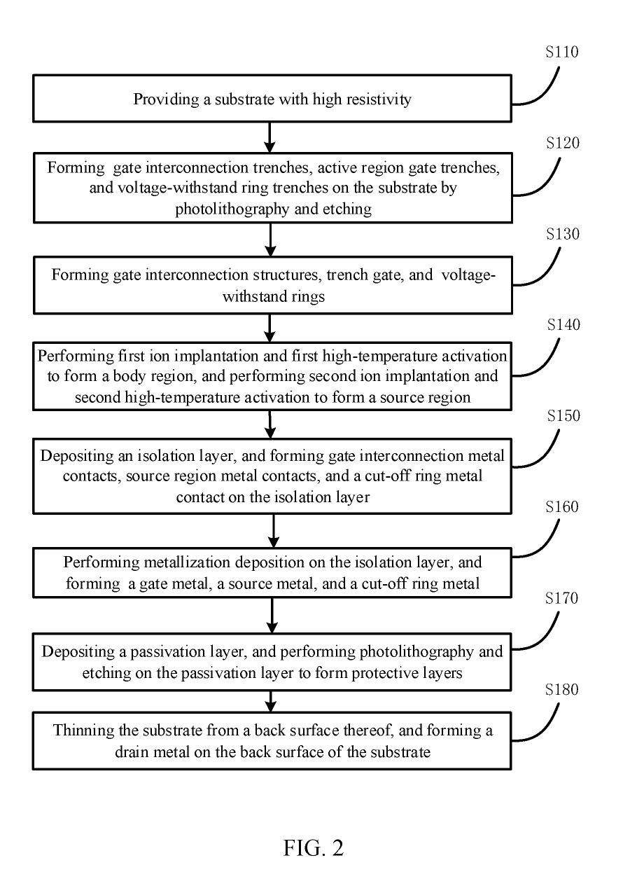

FIG. 2 is a flow chart of a method for manufacturing a MOSFET device with a single-crystal substrate as an epitaxial region according to one embodiment of the present disclosure. The epitaxial region is an area with functions associated with the epitaxial layer. In conventional MOSFET devices, the epitaxial layer thereof has a different doping concentration than the substrate, thereby creating a wider space charge region and improving a breakdown voltage of the conventional MOSFET devices. The following description takes an example that a chip group comprises two sub-chips (i.e., a first sub-chip 910 and a second sub-chip 920) for further illustration. Of course, the manufacturing method is also able to be used when the chip group comprises only one sub-chip. The method comprises steps S110-S170.

The step S110 comprises providing a substrate 100 with high resistivity.

The conventional MOSFET device typically adopts a substrate with low resistivity, and a doping concentration of the substrate is high (the higher the doping concentration of the substrate 100, the lower the resistivity). However, in the embodiment, to eliminate a step of growing an epitaxial layer, the substrate 100 with high resistivity (i.e., the substrate 100 with a lower doping concentration) is adopted to replace the substrate with low resistivity in the conventional MOSFET device (a specific resistivity of the substrate 100 is adjusted in conjunction with thermal calculations of subsequent high-temperature processes to enable the MOSFET device to achieve desired voltage-withstand specification.). In the embodiment, an average doping concentration of the substrate 100 is E16 -E17 cm ⁻³, so that the substrate 100 has high resistivity. A thickness of the substrate 100 is 700-800 μm. Optionally, the thickness of the substrate 100 is 775 μm.

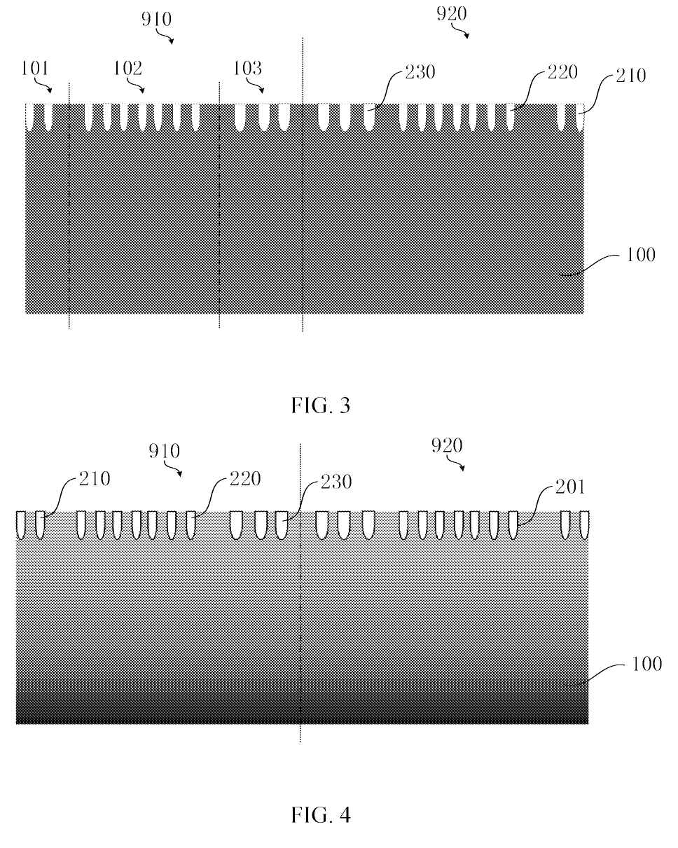

As shown in FIG. 3, the step S120 comprises forming trenches on the substrate 100 by photolithography and etching. The trenches comprise gate interconnection trenches 210 forming in a gate contact region 101, active region gate trenches 220 forming in an active region 102, and voltage-withstand ring trenches 230 forming in a terminal region 103.

The step S130 comprises forming gate interconnection structures 211 respectively in the gate interconnection trenches 210, forming trench gates 221 respectively in the active region gate trenches 220, and forming voltage-withstand rings 231 respectively in the voltage-withstand ring trenches 230. The step S130 comprises sub-steps S131-S133.

The sub-step S131 comprises growing sacrificial oxide layers in the trenches (i.e., the gate interconnection trenches 210, the active region gate trenches 220, and the voltage-withstand ring trenches 230), and removing the sacrificial oxide layers by chemical corrosion.

As shown in FIG. 4, the sub-step S132 comprises growing gate oxide layers 201 respectively in the trenches.

In the steps S131 and S132, a high-temperature process during two oxide layer growth processes (i.e., growth of the sacrificial oxide layer and growth of the gate oxide layer 201) cause a doping concentration of impurities of the substrate 100 to be preliminarily redistributed.

As shown in FIG. 5, the sub-step S133 comprises depositing polysilicon, planarizing and etching portions of the polysilicon outside the trenches by chemical mechanical polishing, thereby forming the gate interconnection structures 211 respectively in the gate interconnection trenches 210, forming the trench gates 221 respectively in the active region gate trenches 220, and forming the voltage-withstand rings 231 respectively in the voltage-withstand ring trenches 230.

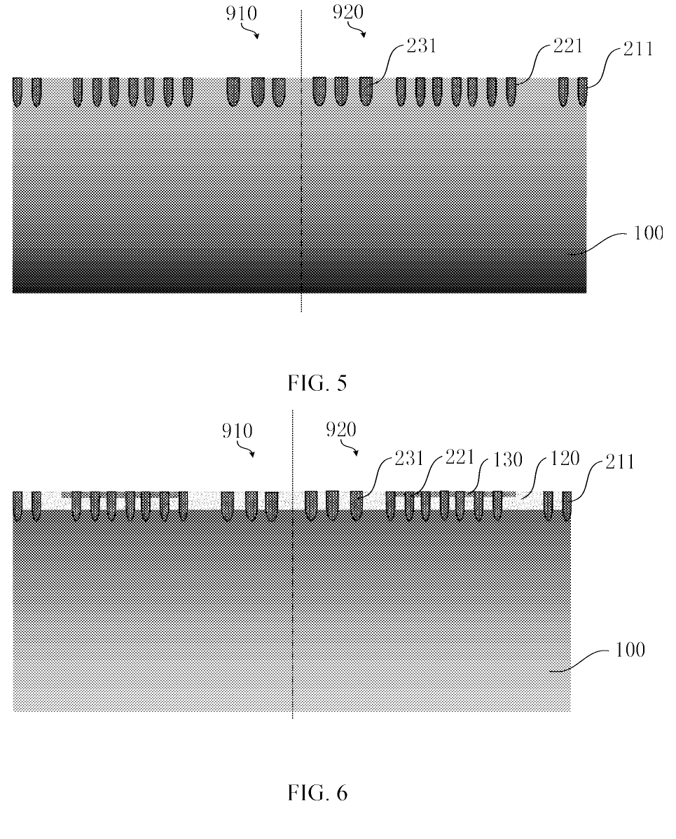

As shown in FIG. 6, the step S140 comprises performing first ion implantation and first high-temperature activation to form a body region 120, and performing second ion implantation and second high-temperature activation to form a source region 130.

Through two high-temperature activation steps in the body region 120 and the source region 130 (especially the high-temperature activation of the body region 120), the doping concentration of the impurities of the substrate 100 is redistributed based on the growth of the sacrificial oxide layer and the growth of the gate oxide layer 201, thereby finally achieving a desired doping concentration distribution on the substrate 100.

In the aforementioned four high-temperature steps, by adjusting the doping concentration of the substrate 100, and leveraging an inherent concentration gradient of the substrate 100 and a high-temperature thermal budget of a subsequent main process (temperature in a range of 90-1200 ℃., a duration of the main process is in a range of 30-60 min), the doping concentration of substrate 100 (the doping concentration is E14-E16 cm⁻³) is redistributed to be similar to that of the voltage-withstand layer (the voltage-withstand layer is a space charge region, or a depletion region, formed between the body region and the drain of the MOSFET device when a voltage is applied to the drain.), thereby enabling the MOSFET device to achieve the desired voltage-withstand specification. Of course, in addition to selecting an initial doping concentration of substrate 100 based on a doping concentration distribution changes in the four high-temperature steps, the temperature of the substrate 100 in the four high-temperature steps is also allowed to be fine-tuned to more accurately achieve a desired doping concentration distribution of the substrate 100 after redistribution.

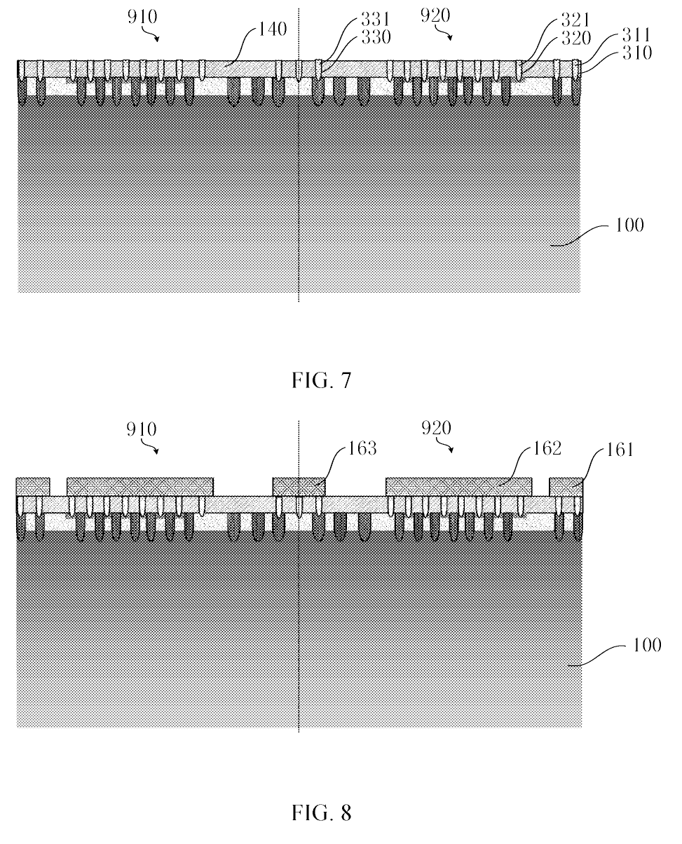

As shown in FIG. 7, the step S150 comprises depositing an isolation layer 140, and forming gate interconnection metal contacts 311, source region metal contacts 321, and cut-off ring metal contacts 331 on the isolation layer 140. The gate interconnection metal contacts 311, the source region metal contacts 321, and the cut-off ring metal contacts 331 run through the isolation layer 140. The gate interconnection metal contacts 311 are respectively connected to the gate interconnection structures 211, the source region metal contacts 321 are connected to the source region 130, and the cut-off ring metal contacts 331 are connected to one of the voltage-withstand rings 231 farthest away from the gate interconnection structures (i.e, the one of the voltage-withstand rings 231 farthest away from the source region 130). The step S150 comprises sub-steps S151-S153.

The sub-step S151 comprises depositing silicon dioxide on the substrate 100 to form the isolation layer 140.

The sub-step S152 comprises forming contact holes running through the isolation layer 140 on the isolation layer 140.

The contact holes comprise gate interconnection contact holes 310 respectively extending into the gate interconnection structures 211, active region contact holes 320 extending into the source region, and a cut-off ring contact holes 330 extending into the corresponding voltage-withstand rings 231.

The sub-step S153 comprises depositing a metal in the contact holes to form the gate interconnection metal contacts 311 respectively in the gate interconnection contact holes 310, the source region metal contacts 321 respectively in the active region contact holes 320, and the cut-off ring metal contact 331 in the cut-off ring contact hole 330.

As shown in FIG. 8, the step S160 comprises performing metallization deposition on the isolation layer 140, and forming bonding pads by photolithography and etching. The bonding pads comprise a gate metal 161 connected to the gate interconnection metal contacts 311, a source metal 162 connected to the source region contacts, and a cut-off ring metal 163 connected to the cut-off ring contacts. The gate metal, the source metal and the cut-off ring metal are isolated from each other.

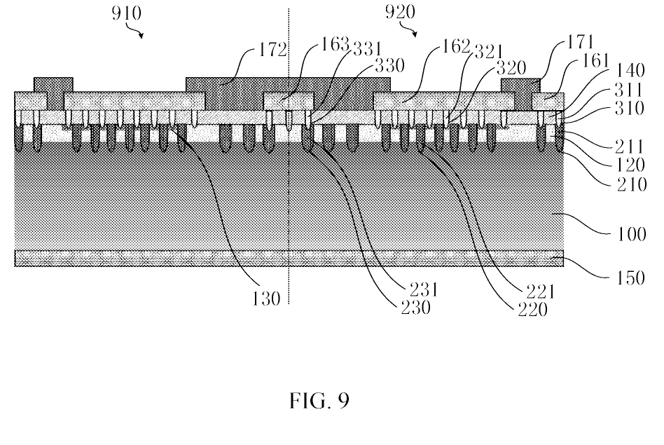

As shown in FIG. 9, the step S170 comprises depositing a passivation layer, and performing photolithography and etching on the passivation layer to form protective layers. The protective layers comprise a first protective layer 171 and a second protective layer 172. The first protective layer 171 is formed between the gate metal and the source metal, and the second protective layer 172 is formed at an upper end and a periphery of the cut-off ring metal.

As shown in FIG. 9, the step S180 comprises thinning the substrate 100 from a back surface thereof, and forming a drain metal 150 on the back surface of the substrate 100.

In a manufacturing process of the MOSFET device of the present disclosure, a thermal process at high temperatures adjusts the resistivity of the substrate 100. As a result, compared to the conventional MOSFET device that has the substrate 100 with low resistivity, the substrate 100 with high resistivity that meets the requirements of the voltage-withstand layer of the MOSFET devices is obtained. By controlling the temperature during the high-temperature process, an originally graded doping concentration in the substrate 100 is redistributed through diffusion, thereby achieving the substrate 100 with the doping concentration roughly equal to that of the voltage-withstand layer. In this way, the MOSFET device is enabled to meet a desired voltage-withstand specification. In the MOSFET device of the present disclosure, since no epitaxial layer needs to be grown, the manufacturing process is simplified, and the manufacturing cost is reduced.

### Embodiment 2

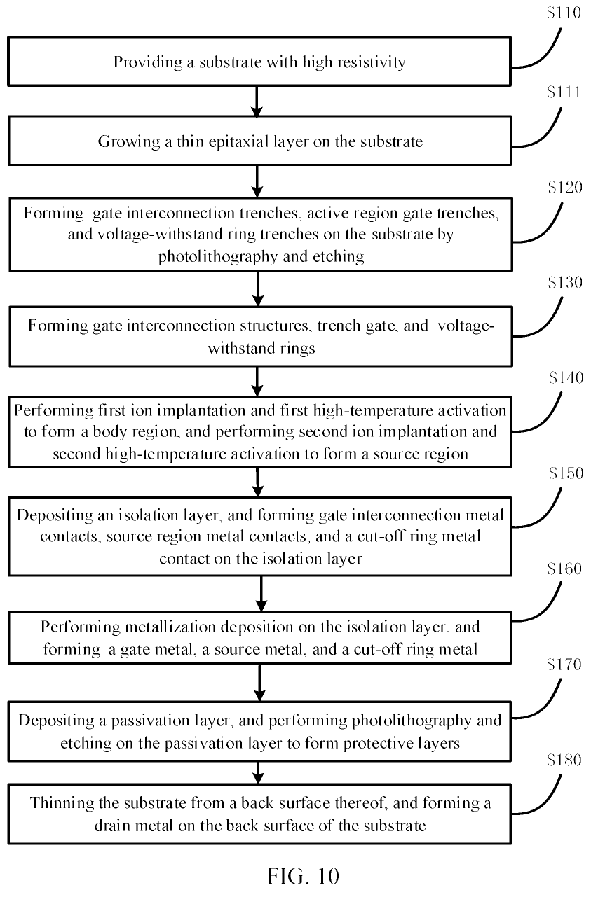

FIG. 10 is a flow chart of the method for manufacturing the MOSFET device according to another embodiment of the present disclosure. The embodiment also takes the example that the chip group comprises two sub-chips (i.e., the first sub-chip 910 and the second sub-chip 920) for further illustration.

By comparing FIGS. 10 and 2, it indicates that a difference between the embodiment and Embodiment 1 is that the embodiment performs a step S111 before performing the step S120:

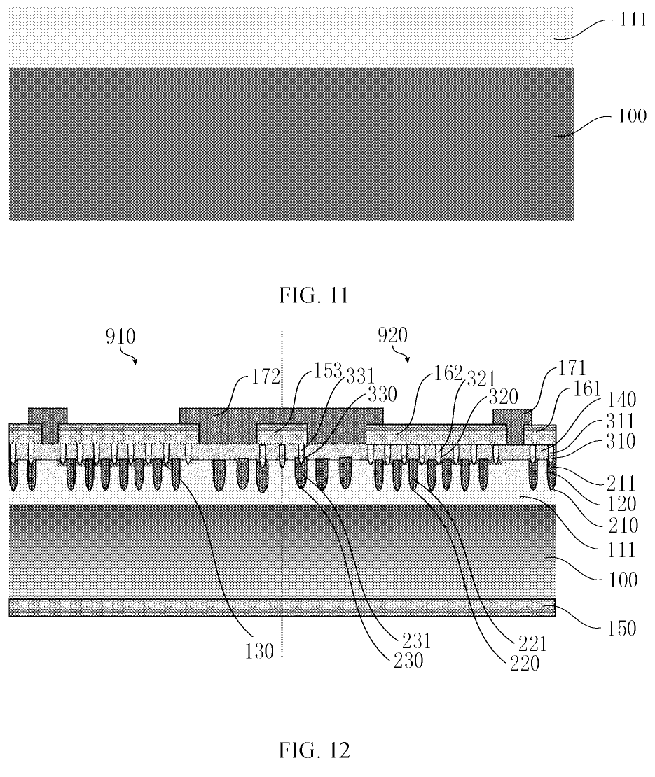

As shown in FIG. 11, the step S111 comprises growing a thin epitaxial layer 111 on the substrate 100. The thin epitaxial layer 111 is either undoped or doped with an extremely low doping concentration of the impurities.

When the thin epitaxial layer 111 is doped with the extremely low doping concentration of the impurities, an impurity doping concentration of the thin epitaxial layer 111 is E12-E13 cm ⁻³ (the doping concentration of the impurities in an epitaxial layer 110 of the conventional MOSFET devices is generally E18-E19cm⁻³).

A thickness of the thin epitaxial layer 111 is determined according to the voltage-withstand specification of different MOSFET devices. The thickness of the thin epitaxial layer 111 is generally 3-20 μm, which is much less than a thickness of the epitaxial layer in the conventional MOSFET device. For example, when V_{ds} = 30V, the thickness of the thin epitaxial layer 111 is generally -5 μm, and when V_{ds} = 100V, the thickness of the thin epitaxial layer 111 is generally 8-10 μm. V_{ds} represents a voltage-withstand specification of the MOSFET device.

FIG. 12 is a schematic diagram of the MOSFET device of the embodiment of the present disclosure. Compared to Embodiment 1, the MOSFET device of the embodiment comprises the thin epitaxial layer 111 with the thickness much less than the epitaxial layer 110 of the conventional MOSFET device. In the embodiment, by providing the thin epitaxial layer 111 that is undoped or doped with the extremely low doping concentration of the impurities, the substrate 100 with a higher doping concentration is obtained, thereby reducing the resistivity of the substrate 100 in the MOSFET device.

### Embodiment 3

The present disclosure further provides a MOSFET device with a single-crystal substrate as an epitaxial region. The MOSFET device is manufactured by the method described above.

The MOSFET device of the embodiment simplifies the manufacturing process, reduces manufacturing costs, and achieves the required voltage-withstand specification.

What is claimed is:

1. A method for manufacturing a metal-oxide-semiconductor field-effect transistor (MOSFET) device with a single-crystal substrate as an epitaxial region, comprising steps:
S110: providing a substrate with high resistivity;
S120: forming trenches on the substrate by photolithography and etching, wherein the trenches comprise gate interconnection trenches, active region gate trenches, and voltage-withstand ring trenches;
S130: forming gate interconnection structures respectively in the gate interconnection trenches, forming trench gates respectively in the active region gate trenches, and forming voltage-withstand rings respectively in the voltage-withstand ring trenches;
S140: performing first ion implantation and first high-temperature activation to form a body region, and performing second ion implantation and second high-temperature activation to form a source region;
S150: depositing an isolation layer, and forming gate interconnection metal contacts, source region metal contacts, and a cut-off ring metal contact on the isolation layer; wherein the gate interconnection metal contacts, the source region metal contacts, and the cut-off ring metal contact run through the isolation layer; wherein the gate interconnection metal contacts are respectively connected to the gate interconnection structures, the source region metal contacts are connected to the source region, and the cut-off ring metal contact is connected to one of the voltage-withstand rings farthest away from the gate interconnection structure;
S160: performing metallization deposition on the isolation layer, and forming bonding pads by photolithography and etching, wherein the bonding pads comprise a gate metal connected to the gate interconnection metal contacts, a source metal connected to the source region contacts, and a cut-off ring metal connected to the cut-off ring contacts; wherein the gate metal, the source metal and the cut-off ring metal are isolated from each other; and
S180: thinning the substrate from a back surface thereof, and forming a drain metal on the back surface of the substrate.

2. The method according to claim 1, wherein an average doping concentration of the substrate is E16 -E17 cm ⁻³ and a thickness of the substrate is 700-800 μm.

3. The method according to claim 1, wherein the step S130 comprises sub-steps:
S131: growing sacrificial oxide layers in the trenches, and removing the sacrificial oxide layers by chemical corrosion;
S132: growing gate oxide layers respectively in the trenches; and
S133: depositing polysilicon, planarizing and etching portions of the polysilicon outside the trenches by chemical mechanical polishing, forming the gate interconnection structures respectively in the gate interconnection trenches, forming the trench gates respectively in the active region gate trenches, and forming the voltage-withstand rings respectively in the voltage-withstand ring trenches.

4. The method according to claim 3, wherein by controlling a temperature during growths of the sacrificial oxide layer and the growth gate oxide layer and forming process of the body region and the source region, a trapezoidal doping concentration of the substrate is redistributed by diffusion, so that a doping concentration of the substrate is roughly equivalent to a doping concentration of the voltage-withstand layer.

5. The method according to claim 1, wherein the step S150 comprises sub-steps:
S151: depositing silicon dioxide on the substrate to form the isolation layer;
S152: forming contact holes running through the isolation layer on the isolation layer, wherein the contact holes comprise gate interconnection contact holes respectively extending into the gate interconnection structures, active region contact holes extending into the source region, and a cut-off ring contact hole extending into the one of the voltage-withstand rings; and
S153: depositing a metal in the contact holes to form the gate interconnection metal contacts respectively in the gate interconnection contact holes, the source region metal contacts respectively in the active region contact holes, and the cut-off ring metal contact in the cut-off ring contact hole.

6. The method according to claim 1, wherein after the step S160, the method further comprises a step:
S170: depositing a passivation layer, and performing photolithography and etching on the passivation layer to form protective layers;
wherein the protective layers comprise a first protective layer and a second protective layer, the first protective layer is formed between the gate metal and the source metal, and the second protective layer is formed at an upper end and a periphery of the cut-off ring metal.

7. The method according to claim 1, wherein before the step S120, the method further comprises a step:
S111: growing a thin epitaxial layer on the substrate;
wherein the thin epitaxial layer is either undoped or doped with an extremely low doping concentration of the impurities.

8. The method according to claim 7, wherein when the thin epitaxial layer is doped with the extremely low doping concentration of the impurities, an impurity doping concentration of the thin epitaxial layer is E12-E13 cm ⁻³.

9. The method according to claim 7, wherein a thickness of the thin epitaxial layer is 3-20 μm.

10. An MOSFET device, comprising: the MOSFET device manufactured by the method according to claim 1.
